(19) United States
(12) Patent Application Publication
(10) Pub. No.: US 2025/0268081 A1
(43) Pub. Date: Aug. 21, 2025

(54) DISPLAY MODULE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Jiali Wang, Beijing (CN); Chienpang Huang, Beijing (CN); Changbo Liu, Beijing (CN); Linchang He, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/857,563

(22) PCT Filed: Sep. 26, 2023
(86) PCT No.: PCT/CN2023/121553

§ 371 Date: Oct. 17, 2024

(30) Foreign Application Priority Data
Oct. 27, 2022 (CN) 202211325449.6

(51) Int. Cl. H10K 59/80; H10K 59/122; H10K 59/38

(52) U.S. Cl. CPC H10K 59/8792; H10K 59/122; H10K 59/38

(57) ABSTRACT

The present disclosure provides a display module, including: a base substrate having a plurality of pixel units, each of the pixel units including a plurality of sub-pixels in different colors; an optical fingerprint identification structure including a plurality of optical sensors arranged on the base substrate and configured to convert fingerprint-reflected light into an electrical signal; a color filter layer including a plurality of color filter units, each of the color filter units including a plurality of color filter members in different colors corresponding to the plurality of sub-pixels; and a light-shielding layer including a plurality of light-shielding members each located between two adjacent color filter members, at least a part of the light-shielding members being provided with a first light-transmitting hole through which the fingerprint-reflected light is transmitted to the optical sensor. The present disclosure also provides a display device.

### CROSS-REFERENCE TO RELATED APPLICATION

This application claims a priority of the Chinese patent application No. 202211325449.6 filed on Oct. 27, 2022, which is incorporated herein by reference in its entirety.

### TECHNICAL FIELD

The present disclosure relates to the manufacture of a display product, in particular to a display module and a display device.

### BACKGROUND

Currently, there are two types of under-screen fingerprint identification schemes, i.e., an optical type and an ultrasonic type. For the ultrasonic type, an under-screen ultrasonic module is used to detect different densities of fingerprint ridges (skin) and valleys (air), so as to construct a three-dimensional (3D) pattern and compare it with patterns stored in a terminal. However, it is impossible to pass through an air layer, so the application thereof is limited. The optical under-screen fingerprint identification scheme is mostly used. In this scheme, on the basis of a self-illumination characteristic of an Organic Light-Emitting Diode (OLED) screen, light from an optical source is reflected by a finger toward a charge-coupled device through a micro lens, so as to obtain a multi-grayscale fingerprint image with black ridges and white valleys, which is capable of being processed through an algorithm. Currently, a Color film On Encapsulation (COE) technology has been proposed, and no polarizer is required, so it is able to reduce a module thickness of the screen, and improve the bending performance of a foldable screen. However, in an existing pol-less structure, due to the use of a Black Matrix (BM) which is almost nontransparent, the light transmittance at a non-pixel region is reduced.

### SUMMARY

An object of the present disclosure is to provide a display module and a display device, so as to solve the problem in the related art where the light transmittance at the non-pixel region is low due to the BM.

In one aspect, the present disclosure provides in some embodiments a display module, including: a base substrate having a plurality of pixel units, each of the pixel units including a plurality of sub-pixels in different colors; an optical fingerprint identification structure including a plurality of optical sensors arranged on the base substrate and configured to convert fingerprint-reflected light into an electrical signal; a color filter layer including a plurality of color filter units, each of the color filter units including a plurality of color filter members in different colors corresponding to the plurality of sub-pixels; and a light-shielding layer including a plurality of light-shielding members each located between two adjacent color filter members, at least a part of the light-shielding members being provided with a first light-transmitting hole through which the fingerprint-reflected light is transmitted to the optical sensor.

In a possible embodiment of the present disclosure, the pixel unit includes a pixel region and a non-pixel region, and an orthogonal projection of at least one of the first light-transmitting holes onto the base substrate is located within an orthogonal projection of the non-pixel region of one of the pixel units onto the base substrate.

In a possible embodiment of the present disclosure, one of the pixel units includes a first pixel and a second pixel the first pixel includes a sub-pixel in a first color and a sub-pixel in a second color, the second pixel includes a sub-pixel in the first color and a sub-pixel in a third color, the sub-pixel in the first color and the sub-pixel in the second color in the first pixel and the sub-pixel in the first color and the sub-pixel in the third color in the second pixel are arranged in such a manner as to form a criss-crossed shape; and an orthogonal projection of the non-pixel region between the sub-pixel in the first color and the sub-pixel in the second color in the first pixel and the sub-pixel in the first color and the third sub-pixel in the second pixel onto the base substrate is a first projection region, and the orthogonal projection of the first light-transmitting hole onto the base substrate is located in the first projection region.

In a possible embodiment of the present disclosure, the sub-pixel in the first color in the first pixel is arranged opposite to the sub-pixel in the first color in the second pixel along a first direction, the sub-pixel in the second color is arranged opposite to the sub-pixel in the third color along a second direction perpendicular to the first direction, and the first direction is parallel to a row direction of the pixel units.

In a possible embodiment of the present disclosure, the sub-pixel in the first color is a green sub-pixel, the sub-pixel in the second color is a blue sub-pixel, and the sub-pixel in the third color is a red sub-pixel.

In a possible embodiment of the present disclosure, a sectional shape of the sub-pixel in the first color, the sub-pixel in the second color or the sub-pixel in the third color is an oval in a direction parallel to the base substrate, a long axis direction of the oval is parallel to the row direction or a column direction of the pixel units, the first light-transmitting hole includes a first edge close to the oval in the long axis direction of the oval, and the first edge moves in a direction away from the oval so that the first light-transmitting hole is of an irregular shape.

In a possible embodiment of the present disclosure, a sectional shape of the first light-transmitting hole is a convex polygon in the direction parallel to the base substrate, and the first edge is a straight line parallel to a short axis direction of the oval.

In a possible embodiment of the present disclosure, the oval includes a second edge arranged opposite to the first edge in the direction parallel to the base substrate, and a distance between the first edge and a corresponding sub-pixel is the same as a distance between the second edge and a corresponding sub-pixel.

In a possible embodiment of the present disclosure, a metal wiring is further arranged on the base substrate, and the orthogonal projection of the first light-transmitting hole onto the base substrate is located outside an orthogonal projection of the metal wiring onto the base substrate.

In a possible embodiment of the present disclosure, the display module further includes a pixel definition layer arranged on the base substrate, and including a plurality of pixel apertures corresponding to the plurality of sub-pixels and non-aperture regions each located between adjacent pixel apertures, and a plurality of second light-transmitting holes is formed in the non-aperture region at positions corresponding to the first light-transmitting holes respectively.

In a possible embodiment of the present disclosure, the orthogonal projection of the first light-transmitting hole onto the base substrate completely covers an orthogonal projection of the corresponding second light-transmitting hole onto the base substrate.

In a possible embodiment of the present disclosure, an area of the orthogonal projection of the first light-transmitting hole onto the base substrate is greater than an area of the orthogonal projection of the second light-transmitting hole onto the base substrate.

In a possible embodiment of the present disclosure, a light-emitting layer is formed in the pixel aperture of the pixel definition layer, and in a direction parallel to the base substrate, a distance D between two adjacent first light-transmitting holes satisfies

$$D \geq h * tan {sin}^{- 1} ( \frac{1}{n} ) ,$$

where h represents a distance between the light-emitting layer and the light-shielding layer, and n represents a refractive index of a top layer of the display module.

In another aspect, the present disclosure provides in some embodiments a display device including the above-mentioned display module.

The present disclosure has the following beneficial effects. The first light-transmitting holes are formed in the light-shielding layer, so it is able to improve the light transmittance, thereby to improve the accuracy of optical fingerprint identification.

### BRIEF DESCRIPTION OF THE DRAWINGS

FIG. 1 is a schematic view of a display module according to one embodiment of the present disclosure;

FIG. 2 is another schematic view of the display module according to one embodiment of the present disclosure;

FIG. 3 yet another schematic view of the display module according to one embodiment of the present disclosure;

FIG. 4 is a schematic view showing the arrangement of sub-pixels according to one embodiment of the present disclosure;

FIG. 5 is a schematic view showing a position of a fingerprint region;

FIG. 6 is a schematic view showing a projection relationship between a pixel definition layer and a light-shielding layer;

FIG. 7 is a schematic view showing a projection relationship among an anode, the pixel definition layer and the light-shielding layer; and

FIG. 8 is a schematic view showing a projection relationship among a color filter layer, the anode, the pixel definition layer and the light-shielding layer.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

In the embodiments of the present disclosure, it should be appreciated that, such words as “in the middle of”, “on/above”. “under/below”, “left”, “right”, “vertical”, “horizontal”, “inside” and “outside” may be used to indicate directions or positions as viewed in the drawings, and they are merely used to facilitate the description in the present disclosure, rather than to indicate or imply that a device or member must be arranged or operated at a specific position. In addition, such words as “first”, “second” and “third” may be merely used to differentiate different components rather than to indicate or imply any importance.

Referring to FIGS. 1 to 8, the present disclosure provides in some embodiments a display module, which includes: a base substrate 1 having a plurality of pixel units, each of the pixel units including a plurality of sub-pixels in different colors; an optical fingerprint identification structure including a plurality of optical sensors 7 arranged on the base substrate 1 and configured to convert fingerprint-reflected light into an electrical signal; a color filter layer including a plurality of color filter units, each of the color filter units including a plurality of color filter members 5 in different colors corresponding to the plurality of sub-pixels; and a light-shielding layer 4 including a plurality of light-shielding members each located between two adjacent color filter members, at least a part of the light-shielding members being each provided with a first light-transmitting hole 41 through which the fingerprint-reflected light is transmitted to the optical sensor 7.

Light emitted by a light-emitting layer 3 is reflected by a fingerprint, and then received and identified by the optical sensor 7. Light transmittance is reduced due to the existence of the light-shielding layer. In the embodiments of the present disclosure, the first light-transmitting holes 41 are formed in the light-shielding layer so as to improve the light transmittance, thereby to improve the accuracy of the optical fingerprint identification.

During the implementation, the pixel unit includes a pixel region and a non-pixel region, and an orthogonal projection of at least one of the first light-transmitting holes 41 onto the base substrate 1 is located within an orthogonal projection of the non-pixel region of one of the pixel units onto the base substrate 1.

The first light-transmitting hole 41 is arranged in the non-pixel region, so as to prevent a display effect from being adversely affected.

The light-shielding layer includes the light-shielding member located between two adjacent color filter members 5, i.e., the light-shielding member functions as to prevent light leakage, and the first light-transmitting hole 41 is arranged in such a manner as not to affect a light-shielding effect of the light-shielding layer. Hence, in some embodiments of the present disclosure, the first light-transmitting hole 41 is not formed in the light-shielding member between any two adjacent color filter members. In addition, the sub-pixels in the pixel units are arranged on the base substrate 1 in various modes, and such factors as different arrangement modes and shapes of the sub-pixels may also affect parameters of the first light-transmitting hole 41 such as position, size and shape. In a possible embodiment of the present disclosure, the pixel unit includes a first pixel and a second pixel, the first pixel includes a sub-pixel in a first color and a sub-pixel in a second color, and the second pixel includes a sub-pixel in the first color and a sub-pixel in a third color. The sub-pixel in the first color and the sub-pixel in the second color in the first pixel and the sub-pixel in the first color and the sub-pixel in the third color in the second pixel are arranged in such a manner as to form a criss-crossed shape.

An orthogonal projection of the non-pixel region between the sub-pixel in the first color and the sub-pixel in the second color in the first pixel and the sub-pixel in the first color and the third sub-pixel in the second pixel onto the base substrate 1 is a first projection region, and the orthogonal projection of the first light-transmitting hole 41 onto the base substrate 1 is located in the first projection region.

In the embodiments of the present disclosure, each of the first pixel and the second pixel includes sub-pixels in two different colors, and the first pixel and the second pixel include sub-pixels in a same color, i.e., the sub-pixel in the first color. During the arrangement, a plurality of first sub-pixel columns and second sub-pixel columns are arranged alternately along a row direction of the pixel units. The first sub-pixel column includes a plurality of sub-pixels in the first color, and the second sub-pixel column includes a plurality of sub-pixels in the second color and the third color arranged alternately. In a column direction of the pixel units, an orthogonal projection of the sub-pixel in the first color onto the second sub-pixel column is located between the adjacent sub-pixels in the second color and the third color.

Referring to FIG. 4, the first pixel includes a green sub-pixel and a red sub-pixel, and the second pixel includes a blue sub-pixel and a green sub-pixel. For example, one pixel unit includes a green sub-pixel G1, a red sub-pixel R1, a blue sub-pixel B1, and a green sub-pixel G4.

Illustratively, an orthogonal projection of a center point of the sub-pixel in the first color onto the second sub-pixel column is located in the middle of a line connecting center points of adjacent sub-pixels in the second color and the third color.

In the embodiments of the present disclosure, the pixel unit includes the first pixel and the second pixel, i.e., four sub-pixels. The orthogonal projection of the first light-transmitting hole 41 onto the base substrate 1 is located inside a region surrounded by orthogonal projections of the four sub-pixels onto the base substrate 1, i.e., the orthogonal projections of the four sub-pixels enclose the orthogonal projection of the corresponding first light-transmitting hole 41 onto the base substrate 1.

It should be appreciated that, the quantity of first light-transmitting holes 41 corresponding to one pixel unit may be set according to the practical need, and it is related to a size of the non-pixel region surrounded by the plurality of sub-pixels in the pixel unit. In a possible embodiment of the present disclosure, one first light-transmitting hole 41 corresponds to, but not limited to, one pixel unit.

The plurality of sub-pixels in one pixel unit may be arranged in various modes. In a possible embodiment of the present disclosure, the sub-pixel in the first color in the first pixel is arranged opposite to the sub-pixel in the first color in the second pixel along a first direction (direction X in FIG. 4), the sub-pixel in the second color is arranged opposite to the sub-pixel in the third color along a second direction (direction Y in FIG. 4) perpendicular to the first direction, and the first direction is parallel to a row direction of the pixel units.

Referring to FIG. 4, in a possible embodiment of the present disclosure, the sub-pixel in the first color is a green sub-pixel, the sub-pixel in the second color is a blue sub-pixel, and the sub-pixel in the third color is a red sub-pixel, but the present disclosure is not limited thereto.

In a possible embodiment of the present disclosure, a sectional shape of the sub-pixel in the first color, the sub-pixel in the second color or the sub-pixel in the third color is an oval in a direction parallel to the base substrate 1, a long axis direction of the oval is parallel to the row direction or a column direction of the pixel units, the first light-transmitting hole 41 includes a first edge close to the oval in the long axis direction of the oval, and the first edge moves in a direction away from the oval so that the first light-transmitting hole 41 is of an irregular shape.

In a possible embodiment of the present disclosure, a plurality of pixel units forms a pixel group, i.e., a pixel period. In one pixel period, when one of the sub-pixels in the first color, the sub-pixel in the second color and the sub-pixel in the third color at different positions has a shape different from the others, distances between the sub-pixel and the adjacent sub-pixels are different. Correspondingly, the shape, position or size of the first light-transmitting hole 41 corresponding to one pixel unit may be slightly different. For example, the sub-pixel in the second color is of an oval shape, a long axis direction of the oval is parallel to the row direction of the pixel units, and a short axis direction of the oval is parallel to the column direction of the pixel units. At this time, in the direction parallel to the base substrate 1, distances between the sub-pixel in the second color and the adjacent sub-pixels are different. In the row direction of the pixel units, in order to avoid the oval structure, a corresponding edge of the first light-transmitting hole 41 may be indented so that the sectional shape of the first light-transmitting hole 41 is of an irregular shape in the direction parallel to the base substrate 1. For example, in the direction parallel to the base substrate 1, the sectional shape of the first light-transmitting hole 41 is formed after a part of a circle is indented, i.e., a part of the first light-transmitting hole 41 close to the oval is indented to form the irregular shape.

Referring to FIG. 4, in a possible embodiment of the present disclosure, in the direction parallel to the base substrate 1, the sectional shape of the first light-transmitting hole 41 is a convex polygon protruding toward a direction away from the oval. The first edge 401 is indented so that an angle between the first edge 401 and an adjacent edge is less than or equal to 90°, and an angle between any two adjacent edges among the edges other than the first edge 401 is an obtuse angle.

Illustratively, the first edge 401 is, but not limited to, a straight line parallel to the short axis direction of the oval.

In a possible embodiment of the present disclosure, the oval includes a second edge arranged opposite to the first edge 401 in the direction parallel to the base substrate 1, and a distance between the first edge 401 and a corresponding sub-pixel is the same as a distance between the second edge and a corresponding sub-pixel. In this way, in the long axis direction of the oval, the distances between the first light-transmitting hole 41 and the adjacent sub-pixels are the same.

In a possible embodiment of the present disclosure, a metal wiring is further arranged on the base substrate 1, and the orthogonal projection of the first light-transmitting hole 41 onto the base substrate 1 is located outside an orthogonal projection of the metal wiring onto the base substrate 1, so as to prevent the occurrence of any interference caused by the metal wiring on the optical fingerprint identification.

In a possible embodiment of the present disclosure, the display module further includes a pixel definition layer 2 arranged on the base substrate 1, and including a plurality of pixel apertures 22 corresponding to the plurality of sub-pixels and non-aperture regions each located between adjacent pixel apertures 22. A plurality of second light-transmitting holes 21 is formed in the non-aperture region at positions corresponding to the first light-transmitting holes 41 respectively.

In a direction away from the base substrate 1, the light-shielding layer is arranged at a side of the pixel definition layer 2 away from the base substrate 1. The light-emitting layer 3 is formed in the pixel aperture 22 of the pixel definition layer 2, and light emitted by the light-emitting layer 3 is reflected by a fingerprint and then reaches an optical fingerprint identification structure on the base substrate 1 for fingerprint identification. The optical sensor is arranged at a side of the base substrate 1 away from the light-shielding layer. i.e., the fingerprint-reflected light needs to pass through the light-shielding layer 4 and the pixel definition layer 2 sequentially and then is identified by the optical sensor 7. An orthogonal projection of the optical sensor 7 onto the base substrate 1 is located in an orthogonal projection of the non-aperture region onto the base substrate 1. The second light-transmitting hole 21 is formed in the pixel definition layer 2. Through the cooperation of the first light-transmitting hole 41 and the second light-transmitting hole 42, it is able to further improve the light transmittance.

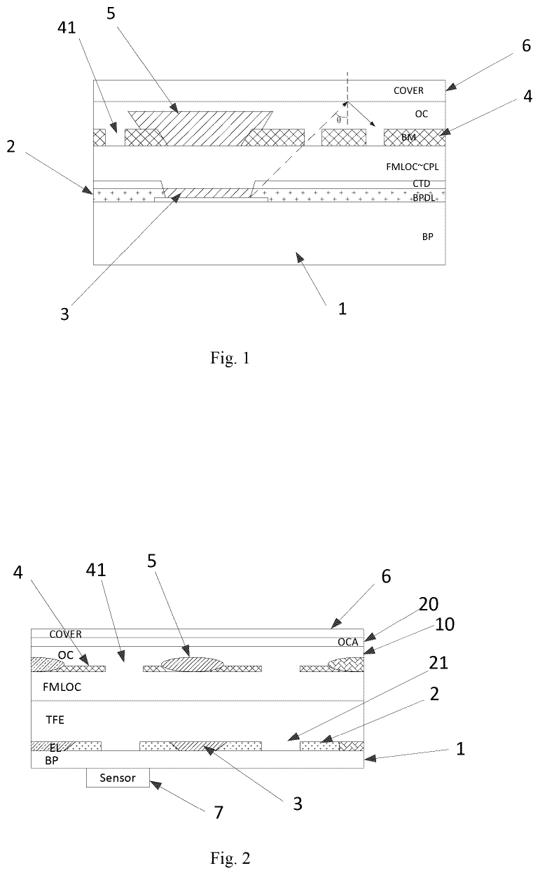

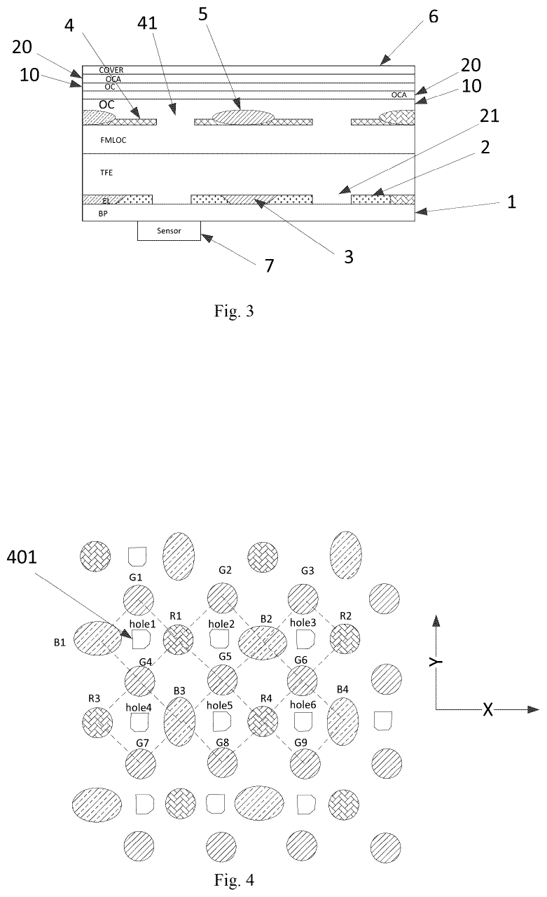

It should be appreciated that, in the display module as shown in FIG. 1, no second light-transmitting hole is formed in the pixel definition layer 2, and the pixel definition layer 2 is made of a light-transmitting material so as to prevent the optical fingerprint identification from being adversely affected when the fingerprint-reflected light is blocked. On the basis of the first light-transmitting hole 21, in order to further improve the light transmittance, the second light-transmitting hole 41 is additionally formed in the pixel definition layer 2 in the display module as shown in FIGS. 2 and 3.

In a possible embodiment of the present disclosure, the orthogonal projection of the first light-transmitting hole 41 onto the base substrate 1 completely covers an orthogonal projection of the second light-transmitting hole 21 onto the base substrate 1. In this way, it is able to prevent a part of the fingerprint-reflected light from not passing through the second light-transmitting hole 21, i.e., prevent the light transmittance from being reduced, when the orthogonal projection of the first light-transmitting hole 41 partially overlaps with that of the second light-transmitting hole 21.

Referring to FIGS. 6 to 8, in a possible embodiment of the present disclosure, an area of the orthogonal projection of the first light-transmitting hole 41 onto the base substrate 1 is greater than an area of the orthogonal projection of the second light-transmitting hole 21 onto the base substrate 1, so as to enable the light passing through the first light-transmitting hole 41 to pass through the second light-transmitting hole 21 to the greatest extent, thereby to improve the light transmittance.

Illustratively, a first aperture 42 is formed in the light-shielding layer 4, and the color filter member 5 is formed on the first aperture 42. An area of an orthogonal projection of the pixel aperture 22 onto the base substrate 1 is smaller than an area of an orthogonal projection of the first aperture 42 onto the base substrate 1.

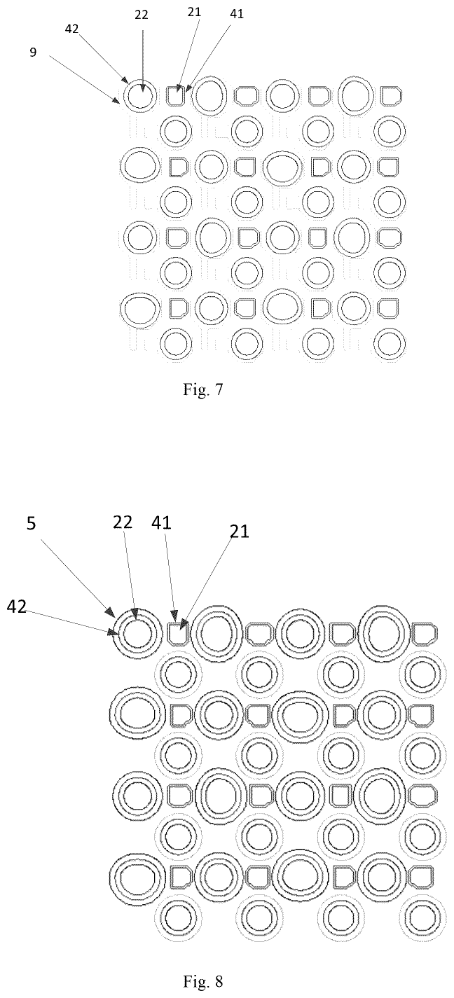

Referring to FIG. 7, illustratively, the display module further includes an anode 9, and an area of an orthogonal projection of the anode 9 onto the base substrate 1 is greater than the area of the orthogonal projection of the first aperture 42 onto the base substrate 1.

Referring to FIG. 8, illustratively, an area of an orthogonal projection of the color filter member 5 onto the base substrate 1 is greater than the area of the orthogonal projection of the first aperture 42 onto the base substrate 1.

In a possible embodiment of the present disclosure, the light-emitting layer 3 is formed in the pixel aperture 22 of the pixel definition layer 2, and in a direction parallel to the base substrate 1, a distance D between two adjacent first light-transmitting holes 41 satisfies

$$D \geq h * tan {sin}^{- 1} ( \frac{1}{n} ) ,$$

where h represents a distance between the light-emitting layer 3 and the light-shielding layer, and n represents a refractive index of a top layer of the display module.

The refractive index of the top layer (i.e., a cover plate 6) of the display module is n, and a minimum angle when total reflection occurs for the light passing through the first light-transmitting hole 41 at an air interface is

$$β = {sin}^{- 1} ( \frac{{n}_{2}}{{n}_{1}} ) = {sin}^{- 1} ( \frac{1}{n} ) = {40.18}^{°} ,$$

where n₁ represents the refractive index of the cover plate 6, and n₂ represents a refractive index of air and has a value of 1.

Referring to FIG. 1, in order to prevent the light leakage at the first light-transmitting hole 41, a reflection angle θ needs to satisfy θ≥B. i.e., in the direction parallel to the base substrate 1, the distance D between two adjacent first light-transmitting holes 41 needs to satisfy

$$D \geq h * tan {sin}^{- 1} ( \frac{1}{n} ) ,$$

where h represents the distance between the light-emitting material layer 3 and the light-shielding layer, and n represents the refractive index of the top layer of the display module.

The present disclosure further provides in some embodiments a display device, which includes the above-mentioned display module.

Illustratively, an over coat (OC) is arranged at a side of the color filter layer away from the base substrate 1 (the OC 10 is made of a transparent resin material for encapsulating and flattening the color filter layer), and an Optically Clear Adhesive (OCA) layer 20 is arranged between the OC 10 and the cover plate 6.

Illustratively, referring to FIG. 3, in a flexible display module, the OC 10, the OCA layer 20, the OC 10, the OCA layer 20 and the cover plate 6 are laminated one on another at the side of the color filter layer away from the base substrate 1.

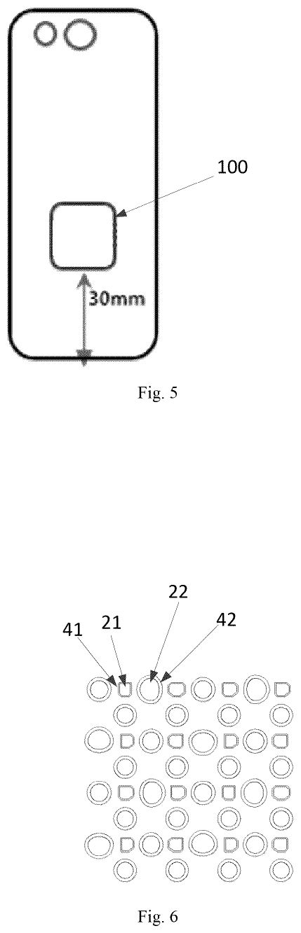

Referring to FIG. 5, illustratively, the cover plate 6 includes a fingerprint region 100 spaced apart from a bottom of a screen (an edge closest to the cover plate) by 30 mm, and a size of the fingerprint region 100 is 9 mm*9 mm, but the present disclosure is not limited thereto.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display module, comprising:
a base substrate having a plurality of pixel units, each of the pixel units comprising a plurality of sub-pixels in different colors;
an optical fingerprint identification structure comprising a plurality of optical sensors arranged on the base substrate and configured to convert fingerprint-reflected light into an electrical signal;
a color filter layer comprising a plurality of color filter units, each of the color filter units comprising a plurality of color filter members in different colors corresponding to the plurality of sub-pixels; and
a light-shielding layer comprising a plurality of light-shielding members each located between two adjacent color filter members, at least a part of the light-shielding members being provided with a first light-transmitting hole through which the fingerprint-reflected light is transmitted to the optical sensor.

2. The display module according to claim 1, wherein the pixel unit comprises a pixel region and a non-pixel region, and an orthogonal projection of at least one of the first light-transmitting holes onto the base substrate is located within an orthogonal projection of the non-pixel region of one of the pixel units onto the base substrate.

3. The display module according to claim 2, wherein one of the pixel units comprises a first pixel and a second pixel the first pixel comprises a sub-pixel in a first color and a sub-pixel in a second color, the second pixel comprises a sub-pixel in the first color and a sub-pixel in a third color, the sub-pixel in the first color and the sub-pixel in the second color in the first pixel and the sub-pixel in the first color and the sub-pixel in the third color in the second pixel are arranged in such a manner as to form a criss-crossed shape; and
an orthogonal projection of the non-pixel region between the sub-pixel in the first color and the sub-pixel in the second color in the first pixel and the sub-pixel in the first color and the third sub-pixel in the second pixel onto the base substrate is a first projection region, and the orthogonal projection of the first light-transmitting hole onto the base substrate is located in the first projection region.

4. The display module according to claim 3, wherein the sub-pixel in the first color in the first pixel is arranged opposite to the sub-pixel in the first color in the second pixel along a first direction, the sub-pixel in the second color is arranged opposite to the sub-pixel in the third color along a second direction perpendicular to the first direction, and the first direction is parallel to a row direction of the pixel unit.

5. The display module according to claim 3, wherein the sub-pixel in the first color is a green sub-pixel, the sub-pixel in the second color is a blue sub-pixel, and the sub-pixel in the third color is a red sub-pixel.

6. The display module according to claim 4, wherein a sectional shape of the sub-pixel in the first color, the sub-pixel in the second color or the sub-pixel in the third color is an oval in a direction parallel to the base substrate, a long axis direction of the oval is parallel to the row direction or a column direction of the pixel units, the first light-transmitting hole comprises a first edge close to the oval in the long axis direction of the oval, and the first edge moves in a direction away from the oval so that the first light-transmitting hole is of an irregular shape.

7. The display module according to claim 6, wherein a sectional shape of the first light-transmitting hole is a convex polygon in the direction parallel to the base substrate, and the first edge is a straight line parallel to a short axis direction of the oval.

8. The display module according to claim 6, wherein the oval comprises a second edge arranged opposite to the first edge in the direction parallel to the base substrate, and a distance between the first edge and a corresponding sub-pixel is the same as a distance between the second edge and a corresponding sub-pixel.

9. The display module according to claim 3, wherein a metal wiring is further arranged on the base substrate, and the orthogonal projection of the first light-transmitting hole onto the base substrate is located outside an orthogonal projection of the metal wiring onto the base substrate.

10. The display module according to claim 3, further comprising a pixel definition layer arranged on the base substrate, and comprising a plurality of pixel apertures corresponding to the plurality of sub-pixels and non-aperture regions each located between adjacent pixel apertures, wherein a plurality of second light-transmitting holes is formed in the non-aperture region at positions corresponding to the first light-transmitting holes respectively.

11. The display module according to claim 10, wherein the orthogonal projection of the first light-transmitting hole onto the base substrate completely covers an orthogonal projection of the corresponding second light-transmitting hole onto the base substrate.

12. The display module according to claim 11, wherein an area of the orthogonal projection of the first light-transmitting hole onto the base substrate is greater than an area of the orthogonal projection of the second light-transmitting hole onto the base substrate.

13. The display module according to claim 10, wherein a light-emitting layer is formed in the pixel aperture of the pixel definition layer, and in a direction parallel to the base substrate, a distance D between two adjacent first light-transmitting holes satisfies
$$D \geq h * tan {sin}^{- 1} ( \begin{matrix}1 \\ n\end{matrix} ) ,$$
where h represents a distance between the light-emitting layer and the light-shielding layer, and n represents a refractive index of a top layer of the display module.

14. A display device comprising the display module according to claim 1.

15. The display device according to claim 14, wherein the pixel unit comprises a pixel region and a non-pixel region, and an orthogonal projection of at least one of the first light-transmitting holes onto the base substrate is located within an orthogonal projection of the non-pixel region of one of the pixel units onto the base substrate.

16. The display device according to claim 15, wherein one of the pixel units comprises a first pixel and a second pixel the first pixel comprises a sub-pixel in a first color and a sub-pixel in a second color, the second pixel comprises a sub-pixel in the first color and a sub-pixel in a third color, the sub-pixel in the first color and the sub-pixel in the second color in the first pixel and the sub-pixel in the first color and the sub-pixel in the third color in the second pixel are arranged in such a manner as to form a criss-crossed shape; and
an orthogonal projection of the non-pixel region between the sub-pixel in the first color and the sub-pixel in the second color in the first pixel and the sub-pixel in the first color and the third sub-pixel in the second pixel onto the base substrate is a first projection region, and the orthogonal projection of the first light-transmitting hole onto the base substrate is located in the first projection region.

17. The display device according to claim 16, wherein the sub-pixel in the first color in the first pixel is arranged opposite to the sub-pixel in the first color in the second pixel along a first direction, the sub-pixel in the second color is arranged opposite to the sub-pixel in the third color along a second direction perpendicular to the first direction, and the first direction is parallel to a row direction of the pixel unit.

18. The display device according to claim 16, wherein the sub-pixel in the first color is a green sub-pixel, the sub-pixel in the second color is a blue sub-pixel, and the sub-pixel in the third color is a red sub-pixel.

19. The display device according to claim 17, wherein a sectional shape of the sub-pixel in the first color, the sub-pixel in the second color or the sub-pixel in the third color is an oval in a direction parallel to the base substrate, a long axis direction of the oval is parallel to the row direction or a column direction of the pixel units, the first light-transmitting hole comprises a first edge close to the oval in the long axis direction of the oval, and the first edge moves in a direction away from the oval so that the first light-transmitting hole is of an irregular shape.

20. The display device according to claim 19, wherein a sectional shape of the first light-transmitting hole is a convex polygon in the direction parallel to the base substrate, and the first edge is a straight line parallel to a short axis direction of the oval.
